(19) United States
(12) Patent Application Publication
(10) Pub. No.: US 2022/0283209 A1
(43) Pub. Date: Sep. 8, 2022

(54) SIGNAL ANALYSIS METHOD, AND APPARATUS FOR THREE-PHASE SYSTEM, AND PROGRAM

(71) Applicant: NEC Corporation, Minato-ku, Tokyo (JP)

(72) Inventor: Murtuza PETLADWALA, Tokyo (JP)

(73) Assignee: NEC Corporation, Minato-ku, Tokyo (JP)

(21) Appl. No.: 17/636,424

(22) PCT Filed: Aug. 29, 2019
(86) PCT No.: PCT/JP2019/033850

§ 371 Date: Feb. 18, 2022

(51) Int. Cl. G01R 25/08; G01R 29/18

(52) U.S. Cl. CPC G01R 25/08; G01R 29/18

(57) ABSTRACT

The present invention provides an apparatus and method enabling to perform a 2-dimensional trajectory analysis applicable for a three-phase system. A signal analysis apparatus generates a three-row and N-column waveform matrix constituted by three N dimensional row vectors having respectively N samples of first to third phase current values obtained from three-phase current signals measured in a three-phase system, where N is the number of samples of each of the three-phase current signals in one cycle of an AC power supply; applies transformation to the waveform matrix to obtain a two-row and N-column matrix constituted by the first and second N dimensional row vectors; performs normalization in amplitude of the first and second N dimensional row vectors, respectively; selects a grid size based on the sample number N; and maps a two dimensional trajectory made up from the first and second normalized N dimensional row vectors on a grid with the grid size selected.

This application is a National Stage Entry of PCT/JP2019/033850 filed on Aug. 29, 2019, the contents of all of which are incorporated herein by reference, in their entirety.

### FIELD

The present invention is related to a signal analysis method and apparatus for a three-phase electric system and program.

### BACKGROUND

Electric current and voltage waveforms of an electric appliance(s) in a home or an office are used for power disaggregation and anomaly detection purposes. VI trajectory of an electric appliance is obtained by plotting voltage against current on two-dimension plane for a defined time period when the appliance is turned on. VI trajectory of each electric appliance represents a unique pattern and is mainly used in non-intrusive load monitoring algorithms as a feature vector.

In NPTL1, a VI trajectory (mutual locus of instantaneous voltage and current waveforms) is used to disaggregate residential overall energy use and predict a profile of each appliance. A feature vector is designed manually and calculated from the VI trajectory like looping direction, area enclosed, non-linearity of mean curve, number of self-intersections, slope of middle segment, and area of right and left segments. Electric appliances used in the disaggregation possess their own unique patterns and the VI trajectory produces promising features for accurate estimation in non-intrusive load monitoring.
[NPLT 1] Taha Hassan, Fahad Javed, Naveed Arshad, “An Empirical Investigation of V-I Trajectory based Load Signatures for Non-Intrusive Load Monitoring”, IEEE Transactions on Smart Grid, Volume: 5 Issue: 2, March 2014.

### SUMMARY

The related technology includes a VI-trajectory of a single-phase electric appliance, where V is a voltage waveform mostly 100V and I is a current waveform measured in a home or office. As compared to a single-phase appliance or system, a three-phase appliance or system mostly used in an industry and factory, the following issues arise:

In a three-phase 4 wire system, three-phase currents Ia, Ib, Ic and three-phase voltages Va, Vb and Vc are measured by 3 sets of power meters (current sensors and voltmeters), as illustrated in FIG. 9A, to produce total six waveforms. This makes realization of a common trajectory projection by the related technology impossible. In FIG. 9A and FIG. 9B, a three-phase 4 wiring system and a three-phase 3 wiring system are illustrated. In FIG. 9A and FIG. 9B, a three-phase Y-Y wiring structure is illustrated, but delta-delta, Y-delta, or delta-Y wiring may, as a matter of course, be adopted.

In a case where a consent is not provided in a distribution board or a breaker, an electrical work by a qualified electrician to attach a voltmeter is needed. Voltage measurement of high voltage line in a factory or industry is not usually performed. In this case, a voltage waveform in three-phase system is not available for analysis.

It is an object to provide an apparatus, method, a non-transitory medium, each enabling to provide 2-dimensional trajectory analysis applicable for a three-phase system.

According to an aspect of the invention, there is provided a signal analysis for a three-phase system, comprising:

a three-phase current signal acquisition and pre-process part that generates a three-row and N-column waveform matrix constituted by three N-dimensional row vectors having respectively N samples of first to third phase current values obtained from three-phase current signals measured in a three-phase system, where N is the number of samples of each of the three-phase current signals in one cycle of an AC power supply;

a three-phase transformation part that applies a transformation to the three-row and N-column waveform matrix to obtain a two-row and N-column matrix constituted by first and second N dimensional row vectors;

a normalization part that performs normalization in amplitude of the first and second N dimensional row vectors to create first and second normalized N dimensional row vectors, respectively;

a grid selection part that determines a grid size based on at least the sample number N; and

a trajectory mapping part that maps a two dimensional trajectory made up from the first and second normalized N dimensional row vectors, on a grid with the grid size determined by the grid selection part.

According to another aspect of the invention, there is provided a signal analysis method for a three-phase system, the method comprising:

generating a three-row and N-column waveform matrix constituted by three N dimensional row vectors having respectively N samples of first to third phase current values obtained from three-phase current signals measured in a three-phase system, where N is the number of samples of each of the three-phase current signals in one cycle of an AC power supply;

applying transformation to the waveform matrix to obtain a two-row and N-column matrix constituted by the first and second N dimensional row vectors;

performing normalization in amplitude of the first and second N dimensional row vectors to create first and second normalized N dimensional row vectors, respectively;

selecting a grid size based on at least the sample number N; and

mapping a two dimensional trajectory made up from the first and second normalized N dimensional row vectors on a grid with the grid size selected.

According to still another aspect of the invention, there is provided a program causing a computer to execute processing comprising:

generating a three-row and N-column waveform matrix constituted by three N dimensional row vectors having respectively N samples of first to third phase current values obtained from three-phase current signals measured in a three-phase system, where N is the number of samples of each of the three-phase current signals in one cycle of an AC power supply;

applying transformation to the waveform matrix to obtain a two-row and N-column matrix constituted by the first and second N dimensional row vectors;

performing normalization in amplitude of the first and second N dimensional row vectors to create first and second normalized N dimensional row vectors, respectively;

selecting a grid size based on at least the sample number N; and

mapping a two dimensional trajectory made up from the first and second normalized N dimensional row vectors on a grid with the grid size selected.

According to yet another aspect of the invention, there is provided a computer-readable recording medium (non-transitory medium) storing therein a program causing a computer to execute processing comprising:

generating a three-row and N-column waveform matrix constituted by three N dimensional row vectors having respectively N samples of first to third phase current values obtained from three-phase current signals measured in a three-phase system, where N is the number of samples of each of the three-phase current signals in one cycle of an AC power supply;

applying transformation to the waveform matrix to obtain a two-row and N-column matrix constituted by the first and second N dimensional row vectors;

performing normalization in amplitude of the first and second N dimensional row vectors to create first and second normalized N dimensional row vectors, respectively;

selecting a grid size based on at least the sample number N; and

mapping a two dimensional trajectory made up from the first and second normalized N dimensional row vectors on a grid with the grid size selected.

According to the present invention, it is made possible to provide 2-dimensional trajectory in a three-phase system to facilitate analysis of operation of a three-phase appliance in various applications like monitoring, anomaly detection and predictions.

### BRIEF DESCRIPTION OF DRAWINGS

FIG. 1 is a diagram illustrating the configuration of a first example embodiment of the present invention.

FIG. 2 is a block diagram illustrating detailed processes of the first example embodiment of the present invention.

FIGS. 3A-3C illustrate display result of the detailed processes in FIG. 2.

FIGS. 4D-4F illustrate display result of the detailed processes in FIG. 2.

FIG. 5 is a diagram illustrating specific operations of a three-phase appliance (drilling machine) according to the first example embodiment of the present invention.

FIG. 6 is a flowchart illustrating an example of a trajectory mapping to grid in the first example embodiment of the present invention.

FIG. 7 is a diagram illustrating a second example embodiment of the present invention.

FIG. 8 is a diagram illustrating a first example embodiment of the present invention.

FIG. 9A and FIG. 9B illustrate well known power measurement for three phase 4 wire and three phase 3 wire systems.

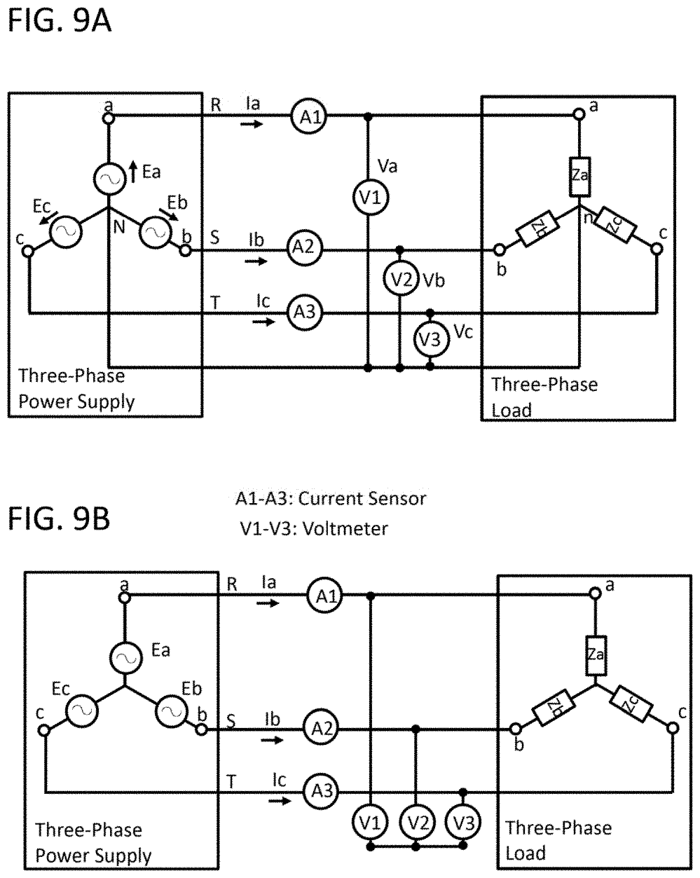

### EXAMPLE EMBODIMENT

According to one aspect of embodiments of the present invention, a signal analysis apparatus obtains a two-dimension trajectory projection using three-phase current waveforms. A three-phase transform can be applied to transform three-phase current vectors into two vectors. The projection of the transformed vectors on a two-dimensional plane creates a unique view that is transformed version of the three-phase current waveforms. In addition, mapping a projected view on a grid structure will provide a projected view in an image format.

According to the one aspect of the embodiments, no voltage waveform is used, thereby un-necessitating measurement of three-phase voltage waveforms.

An amplitude of an AC voltage waveform, i.e., A in the waveform:

A sin(2πf_{b}t+B)

is constant and its shape (periodic waveform) does not change with time. This can dispense with the voltage waveform in the present invention.

In addition, according to the one aspect of the embodiments, a unique view is generated by using only a current waveform, therefore un-necessitating measurement of three-phase voltage waveforms.

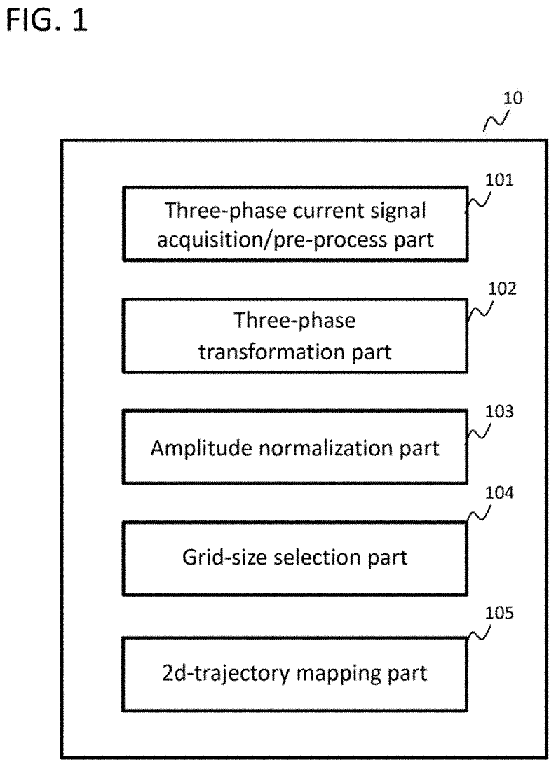

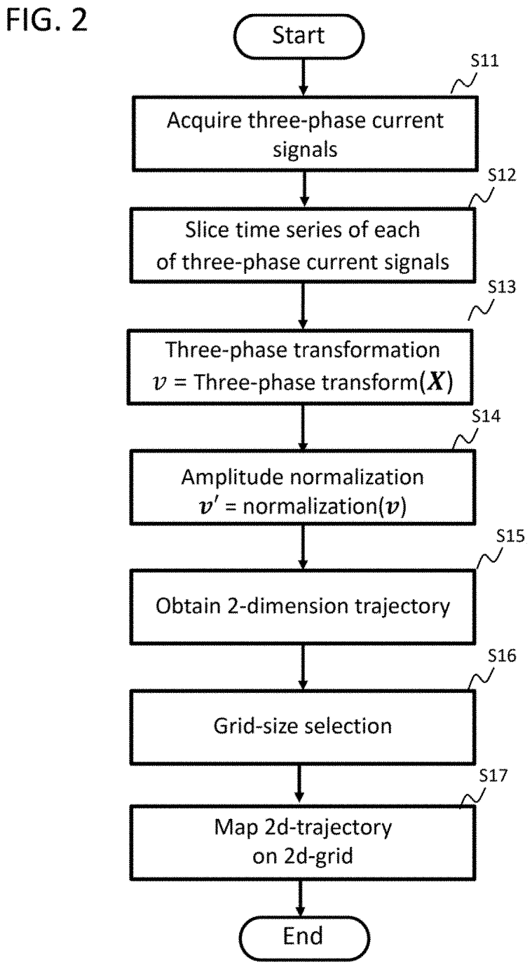

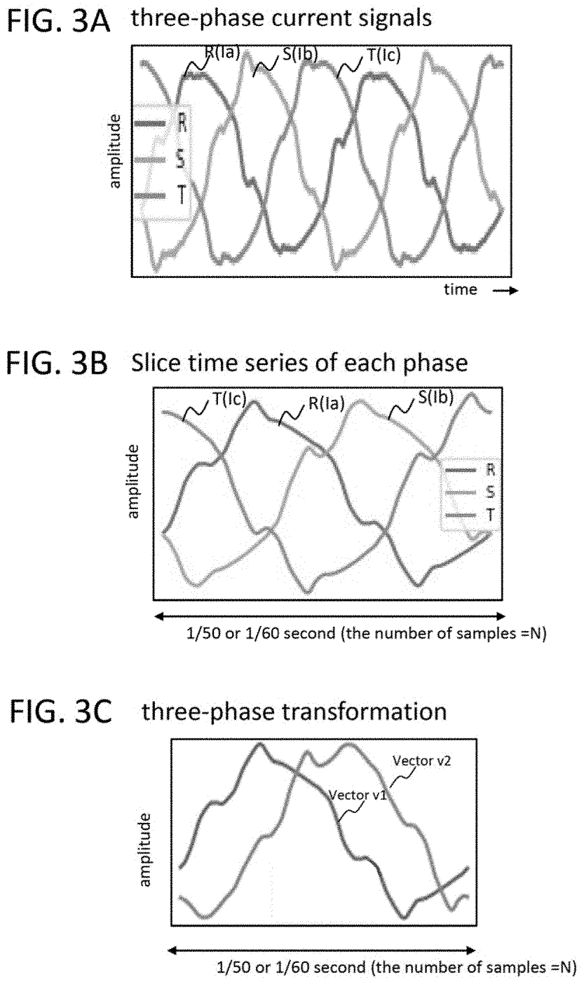

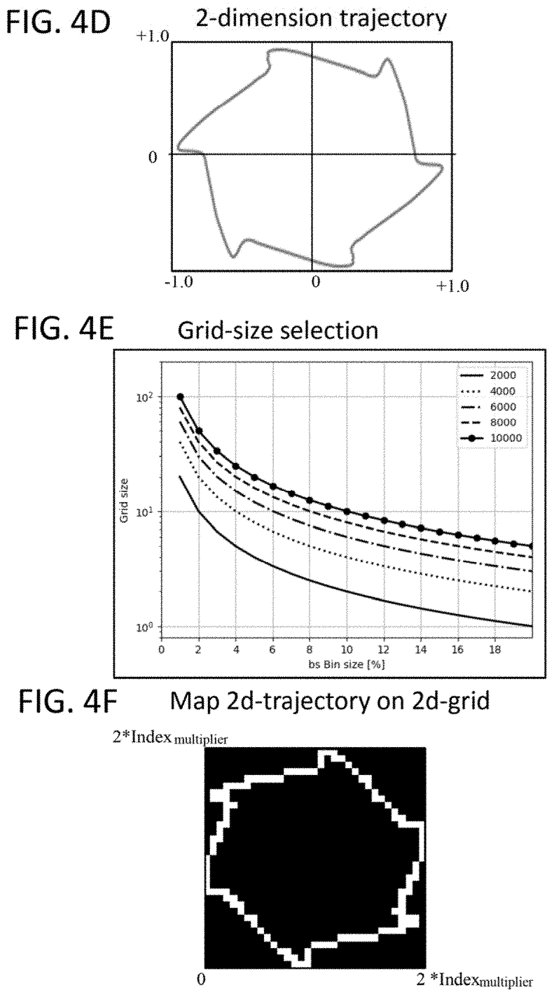

According to an example embodiment of the present invention, as illustrated in FIG. 1, a signal analysis apparatus includes a three-phase current signal acquisition/pre-process part 101, a three-phase transformation part 102, a amplitude normalization part 103, a grid-size selection part 104 and 2d (two-dimensional) trajectory mapping part 105. FIG. 2 is a flowchart illustrating an operation of the first embodiment. FIGS. 3 and 4 are graphical views corresponding to steps of FIG. 2.

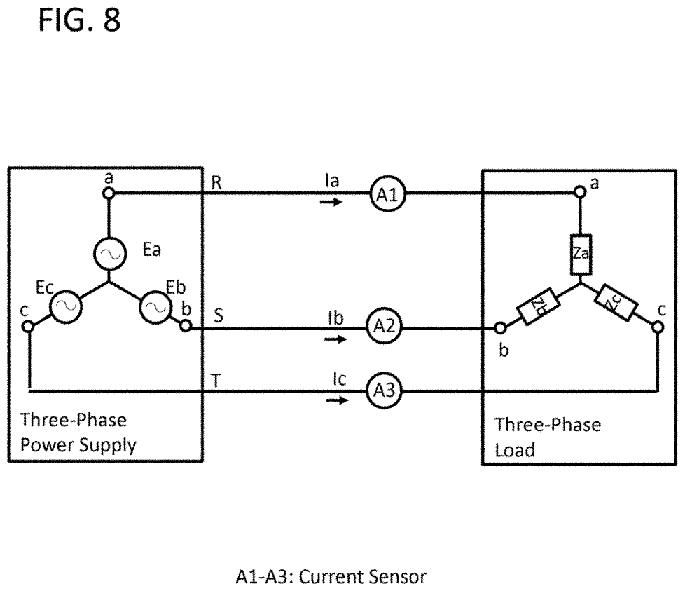

The three-phase current signal acquisition/pre-process part 101 acquires three-phase current waveforms Iₐ, I_{b}, and I_{c} (S11). Three-phase current signals (FIG. 3A): R-phase S-phase, and T-phase are measured as a time series, individually, by three current sensors such as current transformers (CT), on each wire of three-phases, as illustrated in FIG. 8. In the current transformers (CT), an alternating current flowing in a power line produces an alternating magnetic field in a core to induce an alternating current in a secondary winding proportional to a current flowing through its primary.

The three-phase current signal acquisition/pre-process part 101 slices the time series waveform data into individual waveforms, each period of which is one cycle of the AC power frequency (50 Hz or 60 Hz) (S12). Each sliced individual waveform of the three-phase current waveforms Iₐ, I_{b}, and I_{c}, which are shown in FIG. 3B, represents a current in one cycle of a commercial AC power supply ( 1/50 or 1/60 second).

The three-phase current signal acquisition/pre-process part 101 creates a three-row and N-column waveform matrix X:

$$X = [ \begin{matrix}{i}_{a} ( {t}_{1} ) & {i}_{a} ( {t}_{2} ) & … & {i}_{a} ( {t}_{N} ) \\ {i}_{b} ( {t}_{1} ) & {i}_{b} ( {t}_{2} ) & … & {i}_{b} ( {t}_{N} ) \\ {i}_{c} ( {t}_{1} ) & {i}_{c} ( {t}_{2} ) & … & {i}_{c} ( {t}_{N} )\end{matrix} ] \qquad ( 1 )$$

where N is the number of samples of three phase currents in one cycle of an AC power supply ( 1/50 or 1/60 second), and

iₐ(tⱼ), i_{b}(tⱼ), and i_{c}(tⱼ) (j=1, . . . , N) are instantaneous three-phase current values sampled, at timing tⱼ, by analog-to-digital converters in the three current sensors.

A three-phase transformation part 102 applies three-phase transform such as alpha-beta transformation on each instantaneous sliced chunk (one cycle of the AC power supply) of the three-phase current waveforms (S13).

The transformation rotates the three-phase waveform (3-dimension vector) to a DC signal (2-dimension vector), thus simplifying a further analysis. The three-phase transformation part 102 transforms the 3*N waveform matrix X to 2*N waveform matrix v which is made up of N dimensional two waveform row vectors v₁ and v₂ (FIG. 3C).

$$v = [ \begin{matrix}{v}_{1} \\ {v}_{2}\end{matrix} ] = Three - phase transfom ( X ) \qquad ( 2 )$$

Alpha-beta transformation (also known as Clarke transformation) of three-phase currents is given as,

i_{αβγ}=T·i_{abc} (3)

where,

i_{abc} is three-phase current sequence (waveforms),

i_{αβγ} is transformed current sequence (waveforms), and

T is given by

$$T = \frac{2}{3} \cdot [ \begin{matrix}1 & - \frac{1}{2} & - \frac{1}{2} \\ 0 & \frac{\sqrt{3}}{2} & - \frac{\sqrt{3}}{2} \\ \frac{1}{2} & \frac{1}{2} & \frac{1}{2}\end{matrix} ] \qquad ( 4 )$$

Assuming that

$${i}_{a b c} ( t ) = ( \begin{matrix}{i}_{a} ( t ) \\ {i}_{b} ( t ) \\ {i}_{c} ( t )\end{matrix} ) = ( \begin{matrix}\sqrt{2} I cos ( 2 π {f}_{b} t ) \\ \sqrt{2} I cos ( 2 π {f}_{b} t - \frac{2}{3} π ) \\ \sqrt{2} I cos ( 2 π {f}_{b} t - \frac{4}{3} π )\end{matrix} ) \qquad ( 5 )$$

where I is an RMS(Root Mean Square) value of three phase current waveforms: iₐ, i_{b} and i_{c}, and

f_{b} is an AC (alternate current) power supply frequency, we have from the equation (3),

$${i}_{α β γ} ( t ) = ( \begin{matrix}{i}_{α} ( t ) \\ {i}_{β} ( t ) \\ {i}_{γ} ( t )\end{matrix} ) = T ( \begin{matrix}{i}_{a} ( t ) \\ {i}_{b} ( t ) \\ {i}_{c} ( t )\end{matrix} ) = ( \begin{matrix}\sqrt{2} I cos ( 2 π {f}_{b} t ) \\ \sqrt{2} I sin ( 2 π {f}_{b} t ) \\ 0\end{matrix} ) \qquad ( 6 )$$

N number of time series data (one cycle data) of the element i_{αβγ} constitute an N dimensional first row vector v₁ (waveform vector). N number of time series data of the element i_{αβγ} constitute an N dimensional second row vector v₂ (waveform vector). The following is an example based on Alpha-beta transformation.

$${v}_{1} = [ {i}_{α} ( {t}_{1} ) , {i}_{α} ( {t}_{2} ) , … , {i}_{α} ( {t}_{N} ) ] = [ \sqrt{2} I cos ( 2 π {f}_{b} {t}_{1} ) , \sqrt{2} I cos ( 2 π {f}_{b} {t}_{2} ) , … , \sqrt{2} I cos ( 2 π {f}_{b} {t}_{N} ) ] \qquad ( 7 )$$

$${v}_{2} = [ {i}_{β} ( {t}_{1} ) , {i}_{β} ( {t}_{2} ) , … , {i}_{β} ( {t}_{N} ) ] = [ \sqrt{2} I sin ( 2 π {f}_{b} {t}_{1} ) , \sqrt{2} I sin ( 2 π {f}_{b} {t}_{2} ) , … , \sqrt{2} I sin ( 2 π {f}_{b} {t}_{N} ) ] \qquad ( 8 )$$

The first and second N dimensional row vectors v₁ and v₂ constitute a 2*N waveform matrix given as

$$v = [ \begin{matrix}{v}_{1} \\ {v}_{2}\end{matrix} ] = [ \begin{matrix}{i}_{α} ( {t}_{1} ) & {i}_{α} ( {t}_{2} ) & … & {i}_{α} ( {t}_{N} ) \\ {i}_{β} ( {t}_{1} ) & {i}_{β} ( {t}_{2} ) & … & {i}_{β} ( {t}_{N} )\end{matrix} ] \qquad ( 9 )$$

The amplitude normalization part 103 normalizes an amplitude of each of the first and second row vectors. Each vector is divided by an element value which takes the maximum value among the N elements.

$${v}_{j}^{′} = \frac{{v}_{j}}{max ( abs ( {v}_{j} ) )} ( j = 1 , 2 ) \qquad ( 10 )$$

where

vⱼ (j=1,2) is each one of the first and second N dimensional row vectors,

v′ⱼ (j=1,2) is each one of first and second normalized N dimensional row vectors, each element of which takes a value between −1 and +1, and

abs(·) is an operator to take an absolute value of a vector element.

More specifically, regarding the N dimensional row vector of the expressions (7) and (8), the normalized waveform vectors are given as follows:

$$( 11 )$$

$${v}_{1}^{′} = \frac{1}{{max}_{1}} \cdot [ {i}_{α} ( {t}_{1} ) , {i}_{α} ( {t}_{2} ) , … , {i}_{α} ( {t}_{N} ) ] {max}_{1} = max ( abs ( {v}_{1} ) ) = max [ abs ( {i}_{α} ( {t}_{1} ) ) , abs ( {i}_{α} ( {t}_{2} ) ) , … , abs ( {i}_{α} ( {t}_{N} ) ) ]$$

$${v}_{2}^{′} = \frac{1}{{max}_{2}} \cdot [ {i}_{β} ( {t}_{1} ) , {i}_{β} ( {t}_{2} ) , … , {i}_{β} ( {t}_{N} ) ] {max}_{2} = max ( abs ( {v}_{2} ) ) = max [ abs ( {i}_{β} ( {t}_{1} ) ) , abs ( {i}_{β} ( {t}_{2} ) ) , … , abs ( {i}_{β} ( {t}_{N} ) ) ] \qquad ( 12 )$$

where max is a function to return a largest value from a list data provided.

2d trajectory of normalized vectors v₁′ and v₂′ on 2d (two dimensional) plane is illustrated in FIG. 4D, where X axis and Y axis are in a range −1.0 to +1.0.

The grid-size selection part 104 selects a grid size of a final image (S15). If a cell size (bin size) in the grid is too large, different points of 2d trajectories will fall on the same bin, thereby making distinction of the trajectories difficult. If the cell size (bin size) in the grid is too small, two neighboring (similar) points may fall into two different cells (bins) of the grid, thus making two similar trajectories look distinct.

In one of the embodiments, the grid size is given as

$$g r i {d}_{s i z e} = C \cdot \frac{( f s / f b )}{b s} \qquad ( 13 )$$

where C is a constant (e.g., C=½),

fs is a sampling frequency,

fb is a base frequency (AC power supply frequency: 50/60 Hz), and

bs is a bin size of the grid in percentage.

The grid size specifies the number of cells (bins), each of which has an equal size of the two axes (X, Y-axes in a 2d plane). The grid size depends on the number of data points (the number of samples N) in a waveform. The number N of sample data in a sliced waveform chunk (one cycle of the AC power supply frequency: 1/50 or 1/60 second) is given as

$$N = \frac{f s}{{f}_{b}} \qquad ( 14 )$$

The bin size bs in percentage corresponds to an amount of amplitude to be mapped in each bin. Since amplitude of each element of the first and second normalized N dimensional row vectors is normalized to one, a value in percentage of the bin size represents an amount of amplitude to be mapped into one bin. The grid size is reduced to half by the constant C=1/2, since a single waveform is a view on a two-axes image on a plane.

For example, in the case of

a sampling frequency fs: 1000 Hz,

AC power supply frequency fb: 50 Hz, and

bin size bs: 10% percent (=0.1),

the grid size is calculated as:

$${grid}_{s i z e} = \frac{1}{2} \cdot \frac{20}{0.1} = 100$$

That is, in this case, the grid has 100*100 square cells (bins) for a first quadrant: 0≤v₁′≤1, and 0≤v₂′≤1, each having a size of 0.1. The grid has 100*100 square cells (bins) for each of the second to fourth quadrants.

FIG. 4E shows an effect of the Grid-size selection. In FIG. 4E, a horizontal axis is bs that is the bin size in percentage, ranging from 1% to 20% and a vertical axis is the grid size calculated from the expression (13).

The 2d trajectory mapping part 105 maps a 2d trajectory of (v₁′, v₂′) to corresponding grid of cells (FIG. 4F). This enables extraction of 2-d graphical signatures.

Understanding of a time series signal is one of the important and demanding task in an appliance monitoring. In the present embodiment, three-phase current signal may be used for anomaly detection and failure detection systems. In the present invention, a new representation of the current signal which is obtained by mapping 3-phase current waveform signals to image provides a user or manager with easy understanding of an operation of a three-phase appliance. The operation of the three-phase appliance may be a function (s) performed by the appliance either in factories or commercial locations.

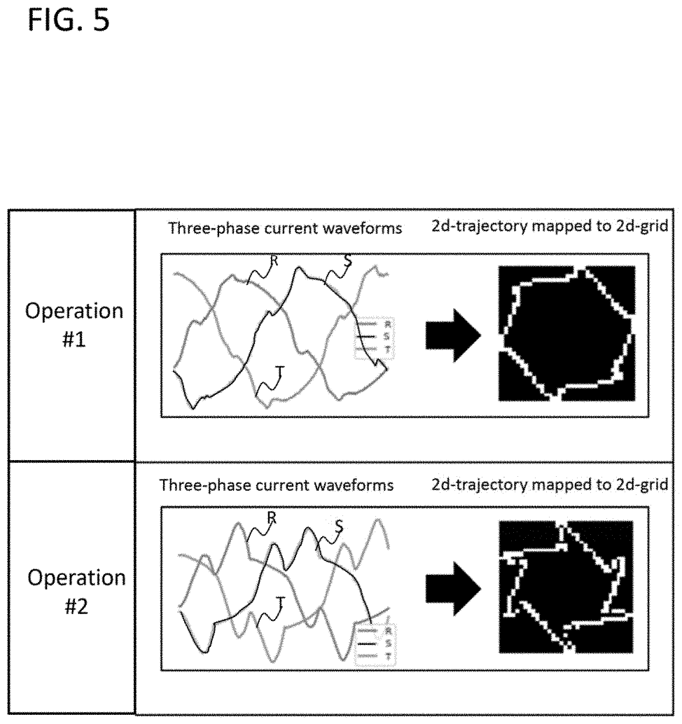

Each image represents an operational behavior of the three-phase appliance. FIG. 5 illustrates an example of signal and its corresponding transformed image. The 3-phase current signal is monitored from a three-phase motor of a drilling machine. In FIG. 5, there are operation field, waveform and 2d trajectory mapped to 2d grid. Operation #1 is an idle time of the machine and operation #2 is a drilling time. It becomes easy to classify the two operations by observing (comparing) the three-phase current signals and also images of 2d trajectory mapped to 2d grid. The further use of these images in developing classification and clustering models is effective as compared with signal-based modelling.

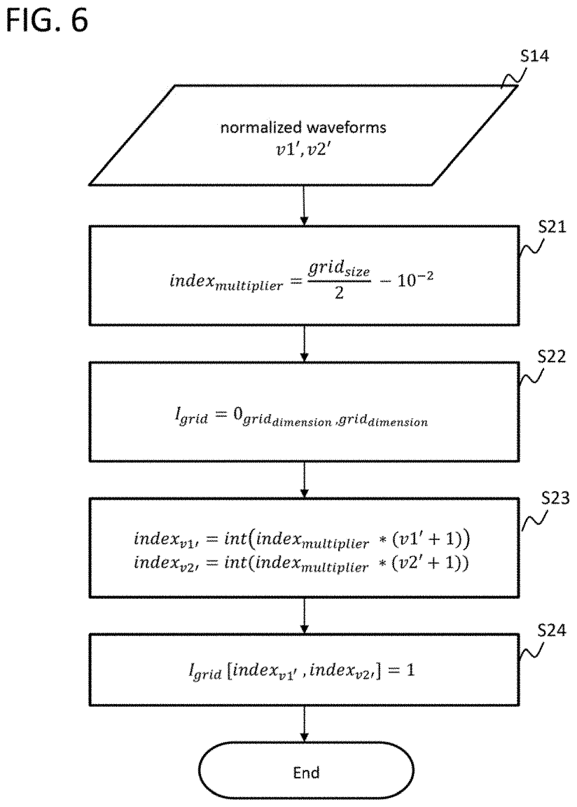

FIG. 6 is a flow chart of mapping normalized waveforms into a 2d (two dimensional) grid. The normalized vectors v₁′ and v₂′ preserve a shape of the waveform signal and is referred as normalized waveforms.

A constant scalar value indexₘᵤₗₜᵢₚₗᵢₑᵣ is calculated by half the grid size calculated by the expression (13). Subtracting of ε (e.g., ε=0.01) from the grid_{size}/2 is to mitigate the problem of dimension multiplication with maximum value of the vector (S21).

$$i n d e {x}_{multiplier} = \frac{g r i {d}_{s i z e}}{2} - ε \qquad ( 15 )$$

An empty grid is initialized with all values to zero (S22).

The normalized waveform vectors v₁′ and v₂′ are multiplied by a constant value: indexₘᵤₗₜᵢₚₗᵢₑᵣ, thereby setting elements of the normalized waveform vectors v₁′ and v₂′ into indexes in the grid (S23).

Since, a value of each element in the normalized waveform vectors v₁′ and v₂′ lies between +1 and −1, each element of the normalized waveform vectors v₁′ and v₂′ is added with a scalar value 1 to change a value of the each element of the normalized waveform vectors v₁′ and v₂′ to a non-negative value.

Each element of the normalized waveform vectors (vᵢ′+1) and (v₂′+1) is multiplied with the constant (scalar) value indexₘᵤₗₜᵢₚₗᵢₑᵣ to generate first (X-axis) and second (Y-axis) grid indexes (index vectors) (S23).

index_{v1′}=int(indexₘᵤₗₜᵢₚₗᵢₑᵣ·(v₁′+1))

index_{v2′}=int(indexₘᵤₗₜᵢₚₗᵢₑᵣ·(v₂′+1)) (16)

where int is a function that returns an integer part of an argument, and

(vᵢ′+1) and (v₂′+1) represent vectors which are obtained by adding 1 to each element of the normalized waveform vectors v₁′ and v₂′, respectively. Each element of vectors (v₁′+1) and (v₂′+1) takes a value between 0 and 2.

index_{v1′} and index_{v2′} are N dimensional row vectors. The i-th element of index_{v1′} is an integer part of indexₘᵤₗₜᵢₚₗᵢₑᵣ. (iₜₕ element of (v₁′+1)). The i-th element of index_{v2′} is an integer part of indexₘᵤₗₜᵢₚₗᵢₑᵣ·(iₜₕ element of (v₂′+1)).

A bin (cell) located at a row: index_{v1′}[i] and a column: index_{v2′}[i] of the matrix I_{grid} is set to one (S24).

$${I}_{grid} [ i n d e {x}_{v {1}^{′}} [ i ] , {index}_{v {2}^{′}} [ i ] ] = 1 ( i = 1 , … , N ) \qquad ( 17 )$$

With the above step, the mapping of 2d trajectory (made up of first and second normalized row vectors: v₁′ and v₂′) on a 2d binary grid, in which each bin takes a value 0 or 1, is performed. A plurality of 2-d trajectories generated respectively from a plurality of cycles (AC power supply frequency) of three-phase current waveforms, each cycle sliced by the three-phase current signal acquisition/pre-process part 101, may be mapped on the same 2d binary grid. Image of the 2d trajectory mapped on the 2d grid may be used to classify image, based on machine learning, such as convolutional neural network.

<Variations>

The binary grid can be replaced by a count grid or a normalized count grid. The count grid is a count of repetition of indexes in the same bin. The grid is initialized with all values to zero. The amplitude values of the normalized vectors: v₁′ and v₂′ falling in a particular element (bin) of the matrix I_{grid} is counted and zero in a particular element (bin) is replaced by this count value. This generates a count grid containing the values zero and count of the amplitude repetition in one bin. A plurality of cycles (AC power supply frequency) of the three-phase current waveforms (m cycles*N samples/cycle) are used to generate the count grid.

The normalized count bin is a normalization of the count grid. The grid is initialized with all values to zero. The amplitude values of the normalized vectors: v₁′ and v₂′ falling in a particular bin is counted and zero in a particular bin is replaced by the count value. The grid is normalized to sum one, where each count value is replaced by count value divided by total counts.

The grid structure is saved as an image representing a view of the transformed three phase current waveforms. Well known image processing techniques and other feature extraction methods may be applied to extract new information from the saved images. The conversion from signal to image visualize higher dimensions on a 2d plane as an image format, which provides a user with new understanding of data.

Variation in mapping function depends on an application and also a feature extraction method.

A two-wattmeter method in which, with reference to FIG. 8, a current sensor (ammeter) A2 is omitted and current (Iₐ, I_{c}) in two lines (R, T) of three phase power lines (R, S, T) and two line voltages V_{ab}, and V_{cb}, which are voltages from the power lines (R, T) with respect to the power line (S) are measured by two voltmeters not shown, where Iₐ+I_{b}+I_{c}=0,

the total power:

W=V_{ab}·Iₐ+V_{bb}·I_{b}+V_{cb}·I_{c}=V_{ab}·Iₐ+V_{cb}·I_{c} (18)

can be accurately measured. Only two current sensors (e.g., A1 and A3 in FIG. 8) are required. In this configuration, two voltmeters are not required, but this does not exclude two watt meters configuration (two ammeters and two voltmeters may be provided to measure for example, total power). The 2*N waveform matrix of the Equation (9) may be created by N sample data of currents (Iₐ, I_{c}) (one cycle of the AC power supply) as listed below.

$$v = [ \begin{matrix}{v}_{1} \\ {v}_{2}\end{matrix} ] = [ \begin{matrix}{i}_{a} ( {t}_{1} ) & {i}_{a} ( {t}_{2} ) & … & {i}_{a} ( {t}_{N} ) \\ {i}_{c} ( {t}_{1} ) & {i}_{c} ( {t}_{2} ) & … & {i}_{c} ( {t}_{N} )\end{matrix} ] \qquad ( 19 )$$

where iₐ(tⱼ) and i_{c}(tⱼ) (j=1, . . . , N) are instantaneous current values sampled, at timing tⱼ, by the current sensors A1 and A3.

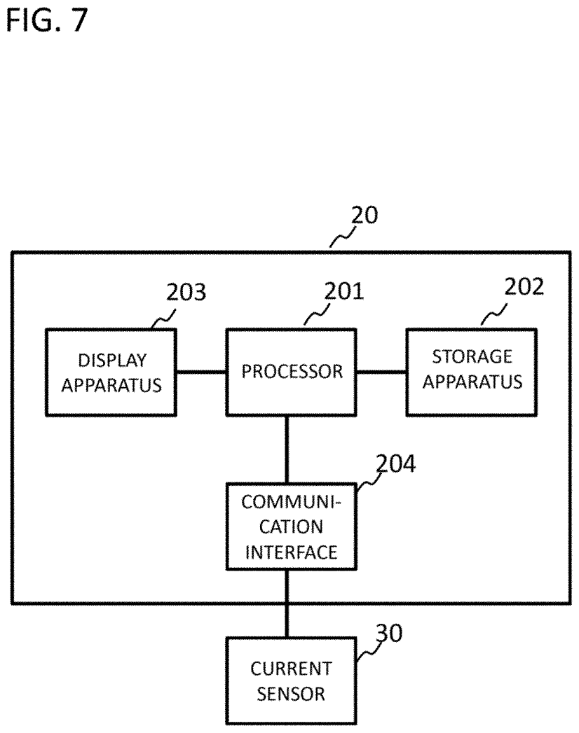

In one of the embodiments, as illustrated in FIG. 7, the apparatus 10 may be implemented on a computer apparatus 20. A computer apparatus 20 such as a server computer includes a processor (a CPU (central processing unit) or a data processing device) 201, a storage apparatus 202, a display apparatus 203, a communication interface 204. The storage apparatus 202 may include at least one of a semiconductor memory (for example, a RAM (a random access memory), a ROM (a read-only memory), an EEPROM (an electrically erasable and programmable ROM)), an HDD (hard disk drive), a CD (compact disc), a DVD (a digital versatile disc), SSD (Solid State Drive), USB (Universal Serial Bus) storage, etc.

The communication interface 204 connects to and communicates with a three-phase current sensor 30. The three-phase current sensor 30 may include three current sensors A1-A3, as illustrated in FIG. 8, which are configured to sample instantaneous three-phase currents Ia-Ic to convert sampled analog current signals to digital time series data by analog-to digital-converters with a synchronized clock. The three-phase current sensor 30 may transmit digital time series data to the computer apparatus 20. The communication interface 204, on reception of the digital time series (three-phase current waveforms) from the three-phase current sensor 30, supplies the digital time series (three-phase current waveforms) to the three-phase current signal acquisition/pre-process part 101 in FIG. 1.

The three-phase current signal acquisition/pre-process part 101 may be configured to obtain three-phase current signals of a three-phase appliance by using disaggregation technique from composite (aggregated) three-phase current signals captured by the three-phase current sensor (CT) 30 arranged in a distribution board.

The signal analysis apparatus 10 according to each example embodiment described above may be realized by storing a program (program instructions and data) that realizes functions of the apparatus 10 in the storage apparatus 202 and causing the processor 201 to read and execute the program.

According to present invention, the transformation from three phase current waveforms to image (2d trajectory mapped on the grid) which is more intuitive to understand the three-phase current waveforms as shown in FIG. 5, opens a new field for signal analysis by using image processing techniques. The grid structure can also be used as feature values which may be supplied as input to diverse machine learning models.

The disclosure of Non Patent Literature 1 given above is hereby incorporated by reference into this specification. The example embodiments may be changed and adjusted in the scope of the entire disclosure (including claims) of the present invention and based on the basic technological concept. In the scope of the claims of the present invention, various disclosed elements may be combined and selected in a variety of ways. That is, it is to be understood that modifications and changes that may be made by those skilled in the art within the scope of the present invention are included.

What is claimed is:

1. A signal analysis apparatus for a three-phase system, comprising:
a processor; and
a memory storing program instructions executable by the processor, wherein the processor is configured to execute the program instructions to implement:
a three-phase current signal acquisition and pre-process part that generates a three-row and N-column waveform matrix constituted by three N-dimensional row vectors having respectively N samples of first to third phase current values obtained from three-phase current signals measured in the three-phase system, where N is the number of samples of each of the three-phase current signals in one cycle of an AC power supply;
a three-phase transformation part that applies a transformation to the three-row and N-column waveform matrix to obtain a two-row and N-column matrix constituted by first and second N dimensional row vectors;
a normalization part that performs normalization in amplitude of the first and second N dimensional row vectors to create first and second normalized N dimensional row vectors, respectively;
a grid selection part that determines a grid size based on at least the sample number N; and
a trajectory mapping part that maps a two dimensional trajectory made up from the first and second normalized N dimensional row vectors, on a grid with the grid size determined by the grid selection part.

2. The signal analysis apparatus according to claim 1, wherein three-phase current signal acquisition and pre-process part slices the three-phase current signals individually into a plurality of sets of triple waveforms, each triple waveforms having a length of one cycle of the AC power supply frequency, to create the three-row and N-column waveform matrix from individual triple waveforms.

3. The signal analysis apparatus according to claim 1, wherein the transformation is alpha-beta transformation.

4. The signal analysis apparatus according to claim 1, wherein the grid size is given by C*N/bs,
where C is a constant,
N is the number of samples in the one cycle of the AC power supply frequency, which is given by dividing a sampling frequency of the three-phase current signals by an AC power supply frequency, and
bs is a bin size.

5. The signal analysis apparatus according to claim 1, wherein the trajectory mapping part initializes the grid to zero and
generates one of:
a binary grid in which a bin on which an element pair of the first and second N dimensional row vectors falls, has a value of one;
a count grid in which a count value indicating a repetition number that an element pair of the first and second N dimensional row vectors falls on a bin, is set in the bin;
a normalized count grid in which a count value indicating a repetition number that an element pair of the first and second N dimensional row vectors falls on a bin, divided by a total count is set in the bin.

6. A signal analysis method for a three-phase system, the method comprising:
generating a three-row and N-column waveform matrix constituted by three N dimensional row vectors having respectively N samples of first to third phase current values obtained from three-phase current signals measured in a three-phase system, where N is the number of samples of each of the three-phase current signals in one cycle of an AC power supply;
applying transformation to the waveform matrix to obtain a two-row and N-column matrix constituted by the first and second N dimensional row vectors;
performing normalization in amplitude of the first and second N dimensional row vectors to create first and second normalized N dimensional row vectors, respectively;
selecting a grid size based on at least the sample number N; and
mapping a two dimensional trajectory made up from the first and second normalized N dimensional row vectors on a grid with the grid size selected.

7. The signal analysis method according to claim 6, comprising
slicing the three-phase current signals individually into a plurality of sets of triple waveforms, each triple waveforms having a length of one cycle of the AC power supply frequency, and creating the three-row and N-column waveform matrix from individual triple waveforms.

8. The signal analysis method according to claim 6, wherein the transformation is alpha-beta transformation.

9. The signal analysis method according to claim 6, wherein the grid size is given by C*N/bs,
where C is a constant,
N is the number of samples in the one cycle of the AC power supply frequency, which is given by dividing a sampling frequency of the three-phase current signals by an AC power supply frequency, and
bs is a bin size.

10. The signal analysis method according to claim 6, comprising
reducing higher dimension data to two dimensions; and
performing grid visualization wherein a plurality of items of the two dimension data are projected as at least a trajectory and saved as a grid image.

11. A non-transitory computer readable medium storing a program causing a computer to execute processing comprising:
generating a three-row and N-column waveform matrix constituted by three N dimensional row vectors having respectively N samples of first to third phase current values obtained from three-phase current signals measured in a three-phase system, where N is the number of samples of each of the three-phase current signals in one cycle of an AC power supply;
applying transformation to the waveform matrix to obtain a two-row and N-column matrix constituted by the first and second N dimensional row vectors;
performing normalization in amplitude of the first and second N dimensional row vectors to create first and second normalized N dimensional row vectors, respectively;
selecting a grid size based on at least the sample number N; and
mapping a two dimensional trajectory made up from the first and second normalized N dimensional row vectors on a grid with the grid size selected.

12. The signal analysis method according to claim 6, wherein the mapping a two dimensional trajectory comprises:
initializing the grid to zero; and
generating one of:
a binary grid in which a bin on which an element pair of the first and second N dimensional row vectors falls, has a value of one;
a count grid in which a count value indicating a repetition number that an element pair of the first and second N dimensional row vectors falls on a bin, is set in the bin;
a normalized count grid in which a count value indicating a repetition number that an element pair of the first and second N dimensional row vectors falls on a bin, divided by a total count is set in the bin.

13. The non-transitory computer readable medium according to claim 11, storing the program causing the computer to execute the processing comprising
slicing the three-phase current signals individually into a plurality of sets of triple waveforms, each triple waveforms having a length of one cycle of the AC power supply frequency, to create the three-row and N-column waveform matrix from individual triple waveforms.

14. The non-transitory computer readable medium according to claim 11, wherein the transformation is alpha-beta transformation.

15. The non-transitory computer readable medium according to claim 11, wherein the grid size is given by C*N/bs,
where C is a constant,
N is the number of samples in the one cycle of the AC power supply frequency, which is given by dividing a sampling frequency of the three-phase current signals by an AC power supply frequency, and
bs is a bin size.

16. The non-transitory computer readable medium according to claim 11, wherein the mapping a two dimensional trajectory comprises processing comprising:
initializing the grid to zero; and
generating one of:
a binary grid in which a bin on which an element pair of the first and second N dimensional row vectors falls, has a value of one;
a count grid in which a count value indicating a repetition number that an element pair of the first and second N dimensional row vectors falls on a bin, is set in the bin;
a normalized count grid in which a count value indicating a repetition number that an element pair of the first and second N dimensional row vectors falls on a bin, divided by a total count is set in the bin.
